(19) United States
(12) Patent Application Publication
(10) Pub. No.: US 2008/0137472 A1
(43) Pub. Date: Jun. 12, 2008

(54) Memory including first and second receivers

(76) Inventors: Josef Schnell, Charlotte, VT (US); Farrukh Aquil, S. Burlington, VT (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/635,276

(22) Filed: Dec. 7, 2006

(51) Int. Cl. G11C 8/18

(52) U.S. Cl. 365/233.11

(57) ABSTRACT

One embodiment provides a memory device including a first receiver and a second receiver. The first receiver is configured to receive a single ended clock signal and provide a first clock signal based on the single ended clock signal to provide a memory function. The second receiver is configured to receive a differential clock signal and provide a second clock signal based on the differential clock signal to provide the memory function. Only one of the first receiver and the second receiver is selected to provide the memory function.

### BACKGROUND

Typically, a computer system includes a number of integrated circuit chips that communicate with one another to perform system applications. Often, the computer system includes a controller, such as a micro-processor, and one or more memory chips, such as random access memory (RAM) chips. The controller and memory communicate with one another to store data and to read the stored data.

The memory chips can be any suitable type of memory including RAM, which can be any suitable type of RAM, such as dynamic RAM (DRAM) including single data rate synchronous DRAM (SDR-SDRAM), double data rate SDRAM (DDR-SDRAM), low power SDR-SDRAM (LPSDR-SDRAM), low power DDR-SDRAM (LPDDR-SDRAM), and graphics DDR-SDRAM (GDDR-SDRAM). Also, the DRAM can be any suitable generation of DRAM, including double data rate two SDRAM (DDR2-SDRAM) and higher generations of DRAM. Usually, each new generation of DRAM operates at an increased data rate from the previous generation.

Customers choose the DRAM they need based on characteristics such as DRAM type, data rate, and memory size. Fluctuating customer demands make it difficult to predict which DRAM types, data rates, and memory sizes will result in the largest profits. Manufacturers provide an ever increasing variety of DRAMs to fit the ever increasing variety of system applications, such as mobile applications, graphics applications, personal computer applications, and server applications. A DRAM device that includes multiple DRAM types can fill the needs of a variety of customers and benefit customers via greater design flexibility and economies of scale that result in lower costs.

Typically, a DRAM chip includes a clock receiver that receives a clock signal to operate. The clock receiver provides a clock signal in the DRAM that is used to provide DRAM functions. An SDR-SDRAM clock receiver provides a read clock signal for outputting read data and a write clock signal for inputting write data. A DDR-SDRAM clock receiver provides a read clock signal for outputting read data, but not a write clock signal for inputting write data. The SDR-SDRAM and DDR-SDRAM clock receivers have different requirements in areas such as functionality, input signals, and performance.

For these and other reasons there is a need for the present invention.

### SUMMARY

The present disclosure describes a memory that includes at least two different clock receivers. One embodiment provides a memory device including a first receiver and a second receiver. The first receiver is configured to receive a single ended clock signal and provide a first clock signal based on the single ended clock signal to provide a memory function. The second receiver is configured to receive a differential clock signal and provide a second clock signal based on the differential clock signal to provide the memory function. Only one of the first receiver and the second receiver is selected to provide the memory function.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of an integrated circuit memory, according to the present invention.

FIG. 2 is a diagram illustrating one embodiment of an integrated circuit memory that includes two input pads coupled to data clock receivers.

FIG. 3 is a diagram illustrating one embodiment of data clock receivers and two input pads.

FIG. 4 is a diagram illustrating one embodiment of memory activated to operate as a LPSDR-SDRAM.

FIG. 5 is a diagram illustrating one embodiment of a memory activated to operate as a LPDDR-SDRAM.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “left,” “right,” “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

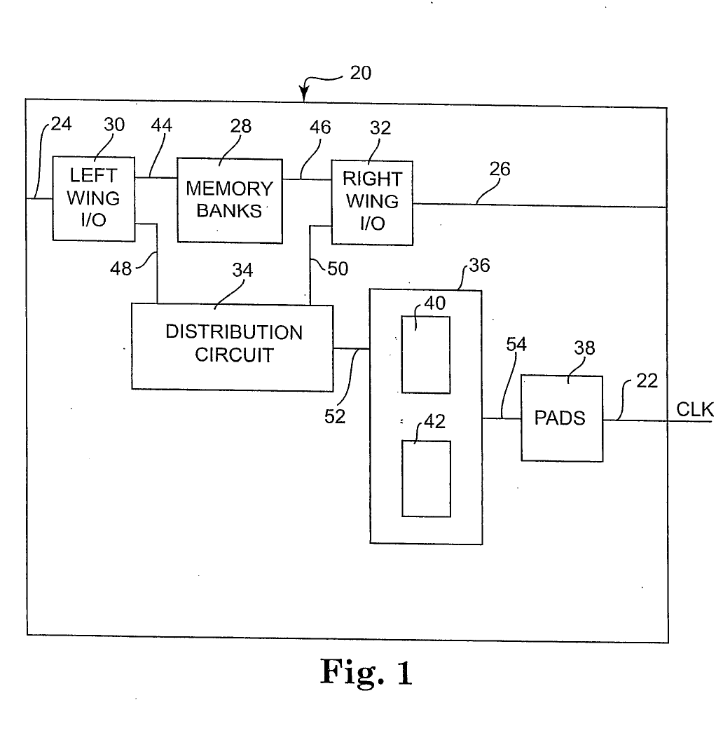

FIG. 1 is a block diagram illustrating one embodiment of an integrated circuit memory (memory) 20, according to the present invention. In one embodiment, memory 20 is a DRAM configured to operate as either a LPSDR-SDRAM or a LPDDR-SDRAM, wherein one of the two DRAM types is selected or activated for operation. In other embodiments, memory 20 can include any suitable memory types and any suitable number of memory types.

Memory 20 is electrically coupled to a package (not shown) via clock path 22, left side input/output (I/O) paths 24, and right side I/O paths 26. In an electrical system, an external circuit, such as a controller, transfers data to and from memory 20 via left side I/O paths 24 and right side I/O paths 26. Memory 20 receives a clock signal CLK at 22. In other embodiments, memory 20 receives clock signals, such as clock signal CLK at 22, on two or more sides of memory 20.

Memory 20 receives a clock signal CLK at 22 that corresponds to the selected memory type in memory 20. Memory 20 provides internal clock signals for the selected memory type via one of two receivers. If the selected memory type is a LPSDR-SDRAM, memory 20 provides a read clock signal for outputting read data and a write clock signal for inputting write data. If the selected memory type is a LPDDR-SDRAM, memory 20 provides a differential read clock signal for outputting read data. In one embodiment, the receiver for the non-selected memory type is not powered.

Memory 20 includes memory banks 28, a left wing I/O circuit 30, a right wing I/O circuit 32, a distribution circuit 34, data clock receivers 36, and input pads 38. As used herein, the term “electrically coupled” is not meant to mean that the elements must be directly coupled together and intervening elements may be provided between the “electrically coupled” elements.

Memory banks 28 are electrically coupled to left wing I/O circuit 30 via left data paths 44 and to right wing I/O circuit 32 via right data paths 46. Distribution circuit 34 is electrically coupled to left wing I/O circuit 30 via left clock signal paths 48 and to right wing I/O circuit 32 via right clock signal paths 50. Also, distribution circuit 34 is electrically coupled to the data clock receivers 36 via clock tree path 52. Input pads 38 are electrically coupled to the data clock receivers 36 via clock input path 54.

Memory 20 includes multiple memory banks at 28. Each of the memory banks 28 includes memory cells, which store data in memory 20. The memory cells correspond to whatever memory types are in memory 20.

In one embodiment, each of the memory banks 28 includes DRAM memory cells, which store data in memory 20. The DRAM memory cells are used if memory 20 operates as a LPSDR-SDRAM or a LPDDR-SDRAM.

In one embodiment, memory cells are in one or more arrays of memory cells. In one embodiment, memory 20 includes four memory banks. In other embodiments, memory 20 includes any suitable number of memory banks.

Left wing I/O circuit 30 receives write data from an external circuit via left side I/O paths 24 and provides the received write data to memory banks 28 for storage via left data paths 44. Left wing I/O circuit 30 receives a clock signal from distribution circuit 34 via left clock signal paths 48 and read data from memory banks 28 via left data paths 44. Left wing I/O circuit 30 provides the read data to the external circuit via left side I/O paths 24.

Right wing I/O circuit 32 receives write data from an external circuit via right side I/O paths 26 and provides the received write data to memory banks 28 for storage via right data paths 46. Right wing I/O circuit 32 receives a clock signal from distribution circuit 34 via right clock signal paths 50 and read data from memory banks 28 via right data paths 46. Right wing I/O circuit 32 provides the read data to the external circuit via right side I/O paths 26.

Input pads 38 receive clock signal CLK at 22 and provide the clock signal to the data clock receivers at 36 via clock input path 54. If memory 20 operates as a LPSDR-SDRAM, one input pad of the input pads 38 receives a single ended clock signal CLK at 22. The single ended clock signal is provided to the data clock receivers at 36 via clock input path 54. If memory 20 operates as a LPDDR-SDRAM, two input pads of the input pads 38 receive a differential clock signal CLK at 22. The differential clock signal is provided to the data clock receivers at 36 via clock input path 54. In one embodiment, the one input pad that receives the single ended clock signal is one of the two input pads that receive the differential clock signal. In other embodiments, the one input pad that receives the single ended clock signal is separate from the two input pads that receive the differential clock signal.

The data clock receivers 36 receive clock signal CLK at 22 via input pads 38 and clock input path 54. The data clock receivers 36 provide a data clock tree signal to distribution circuit 34 via clock tree path 52. The data clock receivers 36 include a single data rate clock receiver 40 and a double data rate clock receiver 42. The single data rate clock receiver 40 is selected or activated if memory 20 is activated to operate as a LPSDR-SDRAM. The double data rate clock receiver 42 is selected or activated if memory 20 is activated to operate as a LPDDR-SDRAM. In other embodiments, the data clock receivers 36 include other suitable clock receivers for receiving a clock signal that corresponds to the memory types in memory 20 and for providing output clock signals that correspond to the memory types in memory 20.

Single data rate clock receiver 40 receives the single ended clock signal via input pads 38 and clock input path 54. Single data rate clock receiver 40 provides a data read clock tree signal and a data write clock tree signal based on the single ended clock signal. Distribution circuit 34 receives the data read clock tree signal and the data write clock tree signal via clock tree path 52.

Double data rate receiver 42 receives the differential clock signal via input pads 38 and clock input path 54. Double data rate clock receiver 42 provides a differential output clock tree signal based on the differential clock signal. Distribution circuit 34 receives the differential output clock tree signal via clock tree path 52.

Single data rate clock receiver 40 and double data rate clock receiver 42 are configured to receive different input signals and to provide different output signals. Also, single data rate clock receiver 40 and double data rate clock receiver 42 are optimized to provide different functions and for AC performance. In one embodiment, single data rate clock receiver 40 and double data rate clock receiver 42 receive different supply voltages. In one embodiment, single data rate clock receiver 40 and double data rate clock receiver 42 provide different output voltage levels. In one embodiment, single data rate clock receiver 40 and double data rate clock receiver 42 receive different input voltage levels.

Distribution circuit 34 receives the data clock tree signal and provides a distributed clock signal that is based on the data clock tree signal. The distributed clock signal is buffered and provided to left wing I/O circuit 30 via left clock signal paths 48 and to right wing I/O circuit 32 via right clock signal paths 50.

If memory 20 is activated to operate as a LPSDR-SDRAM, distribution circuit 34 receives the data read clock tree signal and the data write clock tree signal. Distribution circuit 34 provides a distributed data read clock signal based on the data read clock tree signal and a distributed data write clock signal based on the data write clock tree signal. The distributed data read clock signal and the distributed data write clock signal are buffered and provided to left wing I/O circuit 30 via left clock signal paths 48 and to right wing I/O circuit 32 via right clock signal paths 50. Left wing I/O circuit 30 and right wing I/O circuit 32 receive the distributed data read clock signal and the distributed data write clock signal and input write data via the distributed data write clock signal and output read data via the distributed data read clock signal.

If memory 20 is activated to operate as a LPDDR-SDRAM, distribution circuit 34 receives the differential output clock tree signal and provides a distributed differential output clock signal based on the differential output clock tree signal. The distributed differential output clock signal is buffered and provided to left wing I/O circuit 30 via left clock signal paths 48 and to right wing I/O circuit 32 via right clock signal paths 50. Left wing I/O circuit 30 and right wing I/O circuit 32 receive the distributed differential output clock signal and output read data via the distributed differential output clock signal.

In other embodiments, memory 20 includes separate command/address clock receivers including a single data rate clock receiver and a double data rate clock receiver. The command/address clock receivers provide a command/address clock signal to a command/address block in memory 20 to execute commands. These command/address clock receivers are similar to single data rate clock receiver 40 and double data rate clock receiver 42.

In operation as a LPSDR-SDRAM, single data rate clock receiver 40 receives the single ended clock signal CLK at 22 via one of the input pads 38. Single data rate clock receiver 40 provides the data read clock tree signal and the data write clock tree signal based on the single ended clock signal. Distribution circuit 34 receives the data read clock tree signal and the data write clock tree signal and provides the distributed data read clock signal and the distributed data write clock signal. Left wing I/O circuit 30 and right wing I/O circuit 32 receive the distributed data read clock signal and the distributed data write clock signal and input write data via the distributed data write clock signal and output read data via the distributed data read clock signal.

In operation as a LPDDR-SDRAM, double data rate clock receiver 42 receives the differential clock signal CLK at 22 via two of the input pads 38 and double data rate clock receiver 42 provides the differential output clock tree signal. Distribution circuit 34 receives the differential output clock tree signal and provides the distributed differential output clock signal. Left wing I/O circuit 30 and right wing I/O circuit 32 receive the distributed differential output clock signal and output read data via the distributed differential output clock signal.

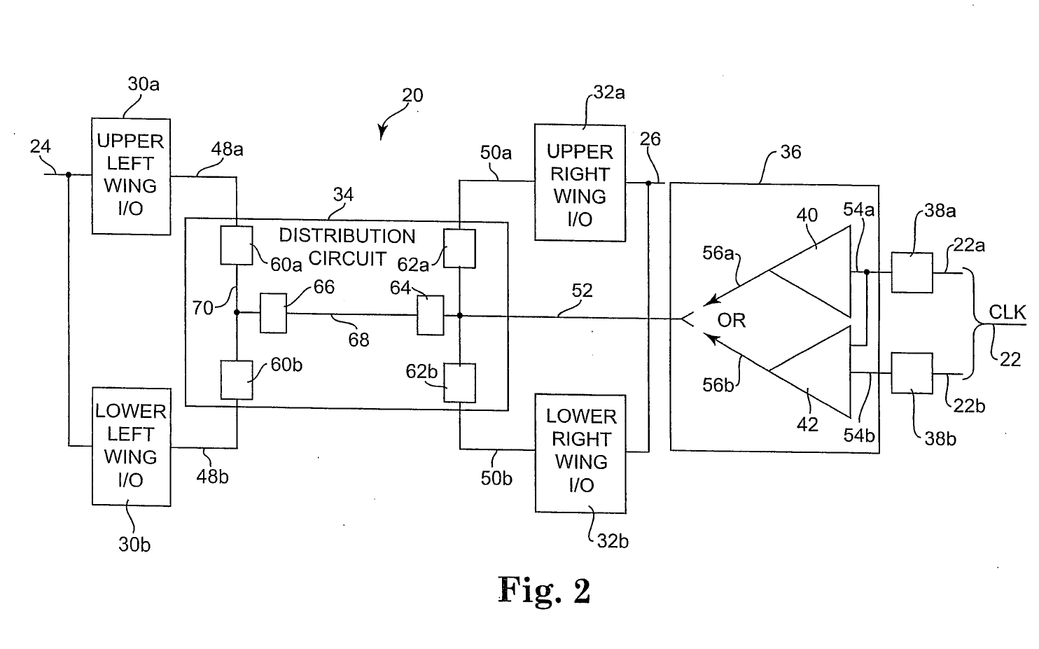

FIG. 2 is a diagram illustrating one embodiment of an integrated circuit memory 20 that includes two input pads 38a and 38b coupled to the data clock receivers 36. Memory 20 includes an upper left wing I/O circuit 30a, a lower left wing I/O circuit 30b, an upper right wing I/O circuit 32a, a lower right wing I/O circuit 32b, distribution circuit 34, data clock receivers 36, and input pads 38a and 38b.

Distribution circuit 34 is electrically coupled to upper left wing I/O circuit 30a via upper left clock signal paths 48a and to lower left wing I/O circuit 30b via lower left clock signal paths 48b. Distribution circuit 34 is electrically coupled to upper right wing I/O circuit 32a via upper right clock signal paths 50a and to lower right wing I/O circuit 32b via lower right clock signal paths 50b. Distribution circuit 34 is electrically coupled to the data clock receivers 36 via clock tree path 52.

Input pads 38a and 38b are electrically coupled to the data clock receivers 36 via clock input paths 54a and 54b. Input pad 38a is electrically coupled to the data clock receivers 36 via clock input path 54a. Input pad 38b is electrically coupled to the data clock receivers 36 via clock input path 54b.

The data clock receivers at 36 include a single data rate clock receiver 40 and a double data rate clock receiver 42. Input pad 38a is electrically coupled to single data rate clock receiver 40 and to double data rate clock receiver 42 via clock input path 54a. Input pad 38b is electrically coupled to double data rate clock receiver 42 via clock input path 54b.

If memory 20 is activated to operate as a LPSDR-SDRAM, the output of single data rate clock receiver 40 is electrically coupled to clock tree path 52 via single data rate output path 56a. In one embodiment, the output of single data rate clock receiver 40 is electrically coupled to clock tree path 52 via single data rate output path 56a in a metal mask step. In one embodiment, single data rate clock receiver 40 is only powered if memory 20 is activated to operate as a LPSDR-SDRAM.

If memory 20 is activated to operate as a LPDDR-SDRAM, the output of double data rate clock receiver 42 is electrically coupled to clock tree path 52 via double data rate output path 56b. In one embodiment, the output of double data rate clock receiver 42 is electrically coupled to clock tree path 52 via double data rate output path 56b in a metal mask step. In one embodiment, double data rate clock receiver 42 is only powered if memory 20 is activated to operate as a LPDDR-SDRAM.

If memory 20 is activated to operate as a LPSDR-SDRAM, input pad 38a receives a single ended clock signal at 22a. Single data rate clock receiver 40 receives the single ended clock signal at 22a via input pad 38a and clock input path 54a. Single data rate clock receiver 40 provides a data read clock tree signal and a data write clock tree signal at 56a based on the single ended clock signal. Distribution circuit 34 receives the data read clock tree signal and the data write clock tree signal at 56a via clock tree path 52.

If memory 20 is activated to operate as a LPDDR-SDRAM, input pads 38a and 38b receive a differential clock signal at 22a and 22b. Double data rate clock receiver 42 receives the differential clock signal via input pads 38a and 38b and clock input paths 54a and 54b. One input of double data rate clock receiver 42 receives one side of the differential clock signal via input pad 38a and clock input path 54a. The other input of double data rate clock receiver 42 receives the other side of the differential clock signal via input pad 38b and clock input path 54b. Double data rate clock receiver 42 provides a differential output clock tree signal at 56b based on the differential clock signal. Distribution circuit 34 receives the differential output clock tree signal at 56b via clock tree path 52.

Distribution circuit 34 includes an upper left buffer circuit 60a, a lower left buffer circuit 60b, an upper right buffer circuit 62a, a lower right buffer circuit 62b, a clock signal distribution buffer 64, and a left clock tree buffer 66. In one embodiment, each of the buffers, including upper left buffer circuit 60a, lower left buffer circuit 60b, upper right buffer circuit 62a, lower right buffer circuit 62b, distribution buffer 64, and left clock tree buffer 66, includes inverting buffers. In one embodiment, each of the buffers includes non-inverting buffers. In other embodiments, each of the buffers includes any suitable type(s) of buffers, such as an inverting buffers and/or non-inverting buffers.

Either single data rate clock receiver 40 or double data rate clock receiver 42 is electrically coupled to the inputs of upper right buffer circuit 62a, lower right buffer circuit 62b, and distribution buffer 64 via clock tree path 52. The output of distribution buffer 64 is electrically coupled to the input of left clock tree buffer 66 via distribution path 68. The output of left clock tree buffer 66 is electrically coupled to the inputs of upper left buffer circuit 60a and lower left buffer circuit 60b via left clock tree path 70.

Upper left buffer circuit 60a is electrically coupled to upper left wing I/O circuit 30a via upper left clock signal paths 48a. Lower left buffer circuit 60b is electrically coupled to lower left wing I/O circuit 30b via lower left clock signal paths 48b. Upper right buffer circuit 62a is electrically coupled to upper right wing I/O circuit 32a via upper right clock signal paths 50a. Lower right buffer circuit 62b is electrically coupled to lower right wing I/O circuit 32b via lower right clock signal paths 50b.

Distribution circuit 34 receives data clock tree signals at 52 and provides distributed clock signals based on the data clock tree signals at 52 to upper left wing I/O circuit 30a, lower left wing I/O circuit 30b, upper right wing I/O circuit 32a, and lower right wing I/O circuit 32b.

Upper right buffer circuit 62a, lower right buffer circuit 62b, and distribution buffer 64 receive the data clock tree signals at 52. Upper right buffer circuit 62a provides upper right distributed clock signals at 50a to upper right wing I/O circuit 32a. Lower right buffer circuit 62b provides lower right distributed clock signals at 50b to lower right wing I/O circuit 32b. Distribution buffer 64 provides distributed clock signals at 68 to left clock tree buffer 66.

Left clock tree buffer 66 receives the distributed clock signals at 68 and provides left clock tree signals at 70 to upper left buffer circuit 60a and lower left buffer circuit 60b via left clock tree path 70. Upper left buffer circuit 60a and lower left buffer circuit 60b receive the left clock tree signals at 70. Upper left buffer circuit 60a provides upper left distributed clock signals at 48a to upper left wing I/O circuit 30a. Lower left buffer circuit 60b provides lower left distributed clock signals at 48b to lower left wing I/O circuit 30b.

If memory 20 is activated to operate as a LPSDR-SDRAM, upper left wing I/O circuit 30a receives the upper left distributed clock signals at 48a from upper left buffer circuit 60a via upper left clock signal paths 48a and read data from the memory banks (FIG. 1). Upper left wing I/O circuit 30a provides the read data to an external circuit via the upper left distributed clock signals at 48a and left side I/O paths 24. Lower left wing I/O circuit 30b receives the lower left distributed clock signals at 48b from lower left buffer circuit 60b via lower left clock signal paths 48b and read data from the memory banks. Lower left wing I/O circuit 30b provides the read data to the external circuit via the lower left distributed clock signals at 48b and left side I/O paths 24. Upper right wing I/O circuit 32a receives the upper right distributed clock signals at 50a from upper right buffer circuit 62a via upper right clock signal paths 50a and read data from the memory banks. Upper right wing I/O circuit 32a provides the read data to the external circuit via the upper right distributed clock signals at 50a and right side I/O paths 26. Lower right wing I/O circuit 32b receives the lower right distributed clock signals at 50b from lower right buffer circuit 62b via lower right clock signal paths 50b and read data from the memory banks. Lower right wing I/O circuit 32b provides the read data to the external circuit via the lower right distributed clock signals at 50b and right side I/O paths 26.

Also, if memory 20 is activated to operate as a LPSDR-SDRAM, upper left wing I/O circuit 30a receives write data from an external circuit via left side I/O paths 24 and inputs the write data via the upper left distributed clock signals at 48a. Lower left wing I/O circuit 30b receives write data from an external circuit via left side I/O paths 24 and inputs the write data via the lower left distributed clock signals at 48b. Upper right wing I/O circuit 32a receives write data from an external circuit via right side I/O paths 26 and inputs the write data via the upper right distributed clock signals at 50a, and lower right wing I/O circuit 32b receives write data from an external circuit via right side I/O paths 26 and inputs the write data via the lower right distributed clock signals at 50b.

If memory 20 is activated to operate as a LPDDR-SDRAM, upper left wing I/O circuit 30a receives the upper left distributed clock signals at 48a from upper left buffer circuit 60a via upper left clock signal paths 48a and read data from the memory banks. Upper left wing I/O circuit 30a provides the read data to an external circuit via the upper left distributed clock signals at 48a and left side I/O paths 24. Lower left wing I/O circuit 30b receives the lower left distributed clock signals at 48b from lower left buffer circuit 60b via lower left clock signal paths 48b and read data from the memory banks. Lower left wing I/O circuit 30b provides the read data to the external circuit via the lower left distributed clock signals at 48b and left side I/O paths 24. Upper right wing I/O circuit 32a receives the upper right distributed clock signals at 50a from upper right buffer circuit 62a via upper right clock signal paths 50a and read data from the memory banks. Upper right wing I/O circuit 32a provides the read data to the external circuit via the upper right distributed clock signals at 50a and right side I/O paths 26. Lower right wing I/O circuit 32b receives the lower right distributed clock signals at 50b from lower right buffer circuit 62b via lower right clock signal paths 50b and read data from the memory banks. Lower right wing I/O circuit 32b provides the read data to the external circuit via the lower right distributed clock signals at 50b and right side I/O paths 26.

In operation as a LPSDR-SDRAM, input pad 38a receives a single ended clock signal at 22a, which is provided to single data rate clock receiver 40 via clock input path 54a. Single data rate clock receiver 40 receives the single ended clock signal at 22a and provides the data read clock tree signal and the data write clock tree signal based on the single ended clock signal. The output of single data rate clock receiver 40 is electrically coupled to clock tree path 52 and distribution circuit 34 receives the data read clock tree signal and the data write clock tree signal at 52. Distribution circuit 34 provides distributed clock signals based on the data read clock tree signal and the data write clock tree signal at 52 to upper left wing I/O circuit 30a, lower left wing I/O circuit 30b, upper right wing I/O circuit 32a, and lower right wing I/O circuit 32b.

Upper left wing I/O circuit 30a receives the upper left distributed clock signals at 48a and provides read data to an external circuit via the data read clock tree signal in the upper left distributed clock signals at 48a. Upper left wing I/O circuit 30a receives write data from an external circuit and inputs the write data via the data write clock tree signal in the upper left distributed clock signals at 48a.

Lower left wing I/O circuit 30b receives the lower left distributed clock signals at 48b and provides read data to an external circuit via the data read clock tree signal in the lower left distributed clock signals at 48b. Lower left wing I/O circuit 30b receives write data from an external circuit and inputs the write data via the data write clock tree signal in the lower left distributed clock signals at 48b.

Upper right wing I/O circuit 32a receives the upper right distributed clock signals at 50a and provides read data to an external circuit via the data read clock tree signal in the upper right distributed clock signals at 50a. Upper right wing I/O circuit 32a receives write data from an external circuit and inputs the write data via the data write clock tree signal in the upper right distributed clock signals at 50a.

Lower right wing I/O circuit 32b receives the lower right distributed clock signals at 50b and provides read data to an external circuit via the data read clock tree signal in the lower right distributed clock signals at 50b. Lower right wing I/O circuit 32b receives write data from an external circuit and inputs the write data via the data write clock tree signal in the lower right distributed clock signals at 50b.

In operation as a LPDDR-SDRAM, a differential clock signal at 22 is provided to double data rate clock receiver 42. Input pad 38a receives one side of the differential clock signal at 22a and input pad 38b receives the other side of the differential clock signal at 22b. Double data rate clock receiver 42 receives the differential clock signal at 22 via clock input paths 54a and 54b. Double data rate clock receiver 42 provides a differential data read clock tree signal based on the differential clock signal at 22.

The output of double data rate clock receiver 42 is electrically coupled to clock tree path 52 and distribution circuit 34 receives the differential data read clock tree signal at 52. Distribution circuit 34 provides distributed clock signals based on the differential data read clock tree signal at 52 to upper left wing I/O circuit 30a, lower left wing I/O circuit 30b, upper right wing I/O circuit 32a, and lower right wing I/O circuit 32b.

Upper left wing I/O circuit 30a receives the upper left distributed clock signals at 48a and provides read data to an external circuit via the differential data read clock tree signal in the upper left distributed clock signals at 48a. Lower left wing I/O circuit 30b receives the lower left distributed clock signals at 48b and provides read data to an external circuit via the differential data read clock tree signal in the lower left distributed clock signals at 48b. Upper right wing I/O circuit 32a receives the upper right distributed clock signals at 50a and provides read data to an external circuit via the differential data read clock tree signal in the upper right distributed clock signals at 50a. Lower right wing I/O circuit 32b receives the lower right distributed clock signals at 50b and provides read data to an external circuit via the differential data read clock tree signal in the lower right distributed clock signals at 50b.

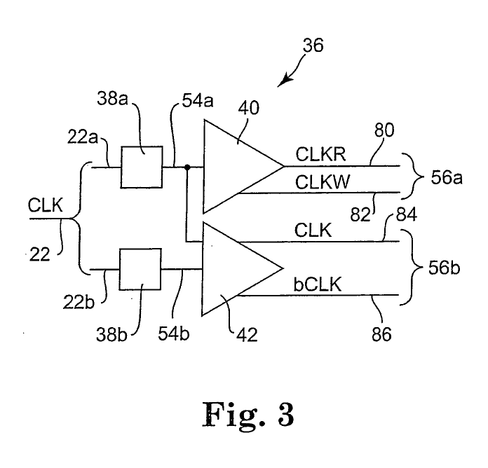

FIG. 3 is a diagram illustrating one embodiment of data clock receivers 36 and two input pads 38a and 38b. Data clock receivers 36 include single data rate clock receiver 40 and double data rate clock receiver 42. Input pad 38a is electrically coupled to single data rate clock receiver 40 and to double data rate clock receiver 42 via clock input path 54a. Input pad 38b is electrically coupled to double data rate clock receiver 42 via clock input path 54b. Input pads 38a and 38b receive clock signal CLK at 22.

If memory 20 is activated to operate as a LPSDR-SDRAM, input pad 38a receives a single ended clock signal at 22a. Single data rate clock receiver 40 receives the single ended clock signal at 22a via input pad 38a and clock input path 54a. Single data rate clock receiver 40 provides a data read clock tree signal CLKR at 80 and a data write clock tree signal CLKW at 82 based on the single ended clock signal. Data read clock tree signal CLKR at 80 and data write clock tree signal CLKW at 82 are provided via single data rate output path 56a.

Data read clock tree signal CLKR at 80 is used to read data from memory 20. Data write clock tree signal CLKW at 82 is used to write data into memory 20. Data read clock tree signal CLKR at 80 and data write clock tree signal CLKW at 82 have different timing requirements and the clock signals can be delayed differently and buffered differently.

Distribution circuit 34 receives the data read clock tree signal CLKR at 80 and the data write clock tree signal CLKW at 82 via single data rate output path 56a and clock tree path 52. Double data rate clock receiver 42 is powered off to reduce power consumption. In other embodiments, double data rate clock receiver 42 can be powered on.

If memory 20 is activated to operate as a LPDDR-SDRAM, input pads 38a and 38b receive a differential clock signal at 22a and 22b. Double data rate clock receiver 42 receives the differential clock signal via input pads 38a and 38b and clock input paths 54a and 54b. One input of double data rate clock receiver 42 receives one side of the differential clock signal via input pad 38a and clock input path 54a. The other input of double data rate clock receiver 42 receives the other side of the differential clock signal via input pad 38b and clock input path 54b. Double data rate clock receiver 42 provides a differential output clock tree signal at 56b based on the differential clock signal. The differential output clock tree signal at 56b includes non-inverting clock signal CLK at 84 and inverting clock signal bCLK at 86. Distribution circuit 34 receives non-inverting clock signal CLK at 84 and inverting clock signal bCLK at 86 via double data rate output path 56b and clock tree path 52. Single data rate clock receiver 40 is powered off to reduce power consumption. In other embodiments, single data rate clock receiver 40 can be powered on.

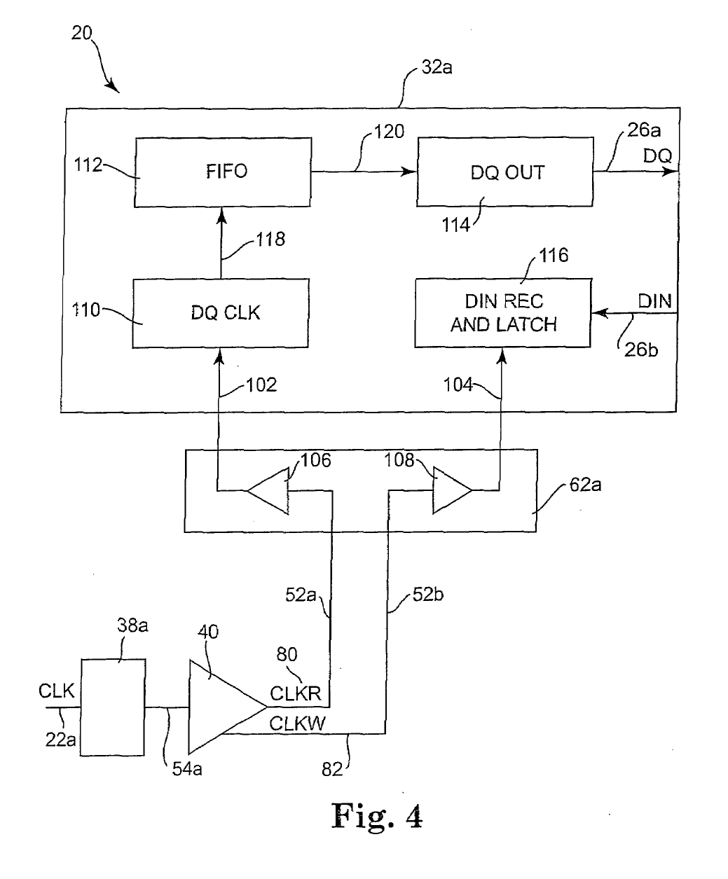

FIG. 4 is a diagram illustrating one embodiment of memory 20 activated to operate as a LPSDR-SDRAM. Memory 20 includes input pad 38a, single data rate clock receiver 40, upper right buffer circuit 62a, and upper right wing I/O circuit 32a.

Input pad 38a is electrically coupled to single data rate clock receiver 40 via clock input path 54a. Single data rate clock receiver 40 is electrically coupled to upper right buffer circuit 62a via read clock tree path 52a and write clock tree path 52b. Upper right buffer circuit 62a is electrically coupled to upper right wing I/O circuit 32a via upper right data read clock signal path 102 and upper right data write clock signal path 104.

Input pad 38a receives a single ended clock signal CLK at 22a and provides the single ended clock signal to single data rate clock receiver 40 via clock input path 54a. Single data rate clock receiver 40 provides data read clock tree signal CLKR at 80 and data write clock tree signal CLKW at 82.

Upper right buffer circuit 62a receives data read clock tree signal CLKR at 80 via read clock tree path 52a and data write clock tree signal CLKW at 82 via write clock tree path 52b. Upper right buffer circuit 62a includes read clock buffer 106 and write clock buffer 108. Read clock buffer 106 and write clock buffer 108 are non-inverting clock buffers. In other embodiments, read clock buffer 106 and write clock buffer 108 can be any suitable buffer types, such as non-inverting and/or inverting clock buffers.

The input of read clock buffer 106 is electrically coupled to the output of single data rate clock receiver 40 via read clock tree path 52a. The input of write clock buffer 108 is electrically coupled to the output of single data rate clock receiver 40 via write clock tree path 52b. The output of read clock buffer 106 is electrically coupled to the upper right wing I/O circuit 32a via upper right data read clock signal path 102. The output of write clock buffer 108 is electrically coupled to the upper right wing I/O circuit 32a via upper right data write clock signal path 104.

The input of read clock buffer 106 receives data read clock tree signal CLKR at 80 and read clock buffer 106 provides a corresponding data read clock tree signal via upper right data read clock signal path 102. The input of write clock buffer 108 receives data write clock tree signal CLKW at 82 and write clock buffer 108 provides a corresponding data write clock tree signal via upper right data write clock signal path 104.

Upper right wing I/O circuit 32a includes a DQ clock circuit 110, a data first-in-first-out (FIFO) circuit 112, a DQ output circuit 114, and write data input receiver and latch 116. Clock circuit 110 is electrically coupled to FIFO circuit 112 via FIFO clock path 118. FIFO circuit 112 is electrically coupled to DQ output circuit 114 via output path 120. Clock circuit 110 receives the data read clock tree signal via upper right data read clock signal path 102 and provides a read clock signal to FIFO circuit 112 via FIFO clock path 118. Data FIFO circuit 112 receives the clock signal and data and provides data to DQ output circuit 114 via output path 120. DQ output circuit 114 outputs data DQ via right side I/O paths 26a.

Write data input receiver and latch 116 receives data write clock tree signal CLKW at 82 via upper right data write clock signal path 104. Also, write data input receiver and latch 116 receives write input data DIN via right side I/O paths 26b. Write data input receiver and latch 116 latches in the write input data DIN via data write clock tree signal CLKW at 82.

In operation, single data rate clock receiver 40 receives the single ended clock signal at 22a and provides data read clock tree signal CLKR at 80 and data write clock tree signal CLKW at 82. Read clock buffer 106 receives data read clock tree signal CLKR at 80 and provides a corresponding data read clock tree signal via upper right data read clock signal path 102. Write clock buffer 108 receives data write clock tree signal CLKW at 82 and provides a corresponding data write clock tree signal via upper right data write clock signal path 104.

Clock circuit 110 receives the data read clock tree signal and provides a read clock signal to FIFO circuit 112. Data FIFO circuit 112 receives the read clock signal and data and provides data to DQ output circuit 114 via output path 120. DQ output circuit 114 outputs data DQ via right side I/O paths 26a.

Write data input receiver and latch 116 receives data write clock tree signal CLKW at 82 and write input data DIN via right side I/O paths 26b. Write data input receiver and latch 116 latches in the write input data DIN via data write clock tree signal CLKW at 82.

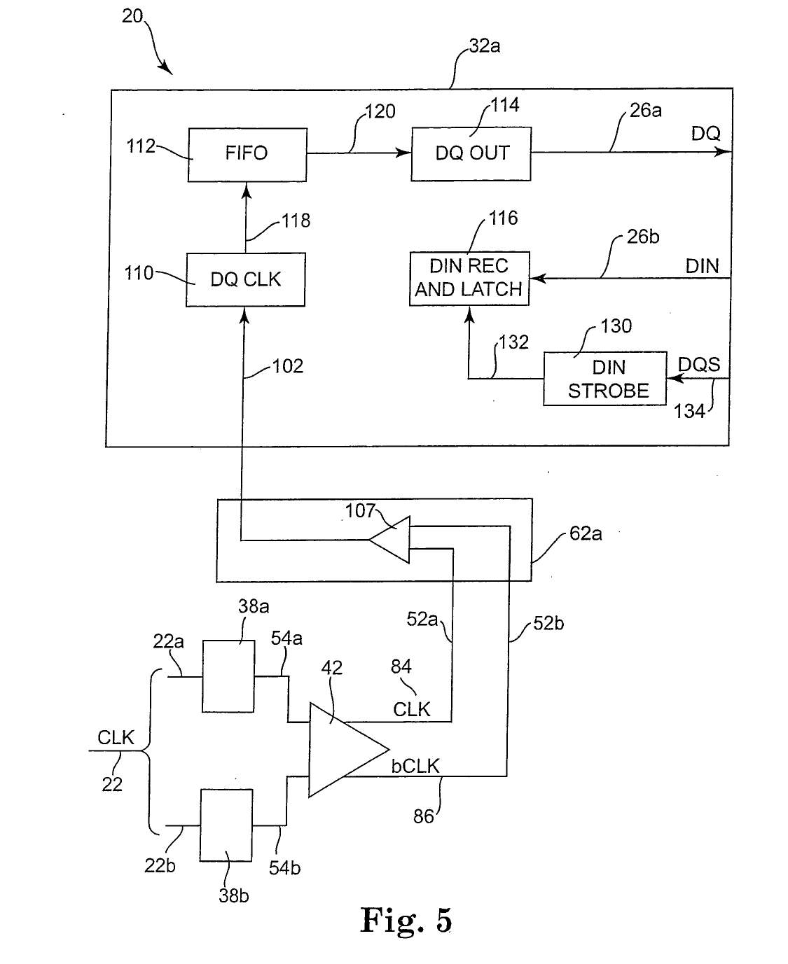

FIG. 5 is a diagram illustrating one embodiment of memory 20 activated to operate as a LPDDR-SDRAM. Memory 20 includes input pads 38a and 38b, double data rate clock receiver 42, upper right buffer circuit 62a, and upper right wing I/O circuit 32a.

Input pad 38a is electrically coupled to double data rate clock receiver 42 via clock input path 54a. Input pad 38b is electrically coupled to double data rate clock receiver 42 via clock input path 54b. Double data rate clock receiver 42 is electrically coupled to upper right buffer circuit 62a via read clock tree path 52a and clock tree path 52b. Upper right buffer circuit 62a is electrically coupled to upper right wing I/O circuit 32a via upper right data read clock signal path 102.

Input pads 38a and 38b receive a differential clock signal CLK at 22. Input pad 38a receives one side of the differential clock signal at 22a and provides the received signal to double data rate clock receiver 42 via clock input path 54a. Input pad 38b receives the other side of the differential clock signal at 22b and provides the received signal to double data rate clock receiver 42 via clock input path 54b. Double data rate clock receiver 42 provides a differential read clock tree signal; one side of the differential read clock tree signal CLK at 84 and the other side of the differential read clock tree signal bCLK at 86.

Upper right buffer circuit 62a receives the one side of the differential read clock tree signal CLK at 84 via read clock tree path 52a and the other side of the differential read clock tree signal bCLK at 86 via clock tree path 52b. Upper right buffer circuit 62a includes read clock buffer 107, which is a non-inverting clock buffer. In other embodiments, read clock buffer 107 can be any suitable buffer type, such as a non-inverting or an inverting clock buffer.

One input of read clock buffer 107 is electrically coupled to an output of double data rate clock receiver 42 via read clock tree path 52a and the other input of read clock buffer 107 is electrically coupled to the other output of double data rate clock receiver 42 via clock tree path 52b. The output of read clock buffer 107 is electrically coupled to the upper right wing I/O circuit 32a via upper right data read clock signal path 102.

The inputs of read clock buffer 107 receive one side of the differential read clock tree signal CLK at 84 and the other side of the differential read clock tree signal bCLK at 86. Read clock buffer 107 provides a corresponding data read clock tree signal via upper right data read clock signal path 102.

Upper right wing I/O circuit 32a includes a DQ clock circuit 110, a data FIFO circuit 112, a DQ output circuit 114, a write data input receiver and latch 116, and a data strobe input circuit 130. Clock circuit 110 is electrically coupled to FIFO circuit 112 via FIFO clock path 118. FIFO circuit 112 is electrically coupled to DQ output circuit 114 via output path 120. Clock circuit 110 receives the data read clock tree signal via upper right data read clock signal path 102 and provides a read clock signal to FIFO circuit 112 via FIFO clock path 118. Data FIFO circuit 112 receives the clock signal and data and provides data to DQ output circuit 114 via output path 120. DQ output circuit 114 outputs data DQ via right side I/O paths 26a.

Write data input receiver and latch 116 is electrically coupled to data strobe input circuit 130 via strobe path 132. Data strobe input circuit 130 receives a data strobe signal DQS at 134 and provides a strobe output signal at 132. Write data input receiver and latch 116 receives the strobe output signal at 132. Also, write data input receiver and latch 116 receives write input data DIN via right side I/O paths 26b. Write data input receiver and latch 116 latches in the write input data DIN via the strobe output signal at 132.

In operation, double data rate clock receiver 42 receives the differential clock signal at 22 and provides one side of the differential read clock tree signal CLK at 84 and the other side of the differential read clock tree signal bCLK at 86. Read clock buffer 106 receives the one side of the differential read clock tree signal CLK at 84 and the other side of the differential read clock tree signal bCLK at 86 and provides a corresponding data read clock tree signal via upper right data read clock signal path 102.

Clock circuit 110 receives the data read clock tree signal and provides a read clock signal to FIFO circuit 112. Data FIFO circuit 112 receives the read clock signal and data and provides data to DQ output circuit 114 via output path 120. DQ output circuit 114 outputs data DQ via right side I/O paths 26a.

Write data input receiver and latch 116 receives the strobe output signal at 132 and write input data DIN via right side I/O paths 26b. Write data input receiver and latch 116 latches in the write input data DIN via the strobe output signal at 132.

Memory 20 includes multiple DRAM types, where one of the DRAM types is selected or activated such as by a metal mask step. Memory 20 receives a clock signal CLK at 22 that corresponds to the selected DRAM type in memory 20. Memory 20 provides internal clock signals for the selected DRAM type via the selected receiver. If the selected DRAM type is a LPSDR-SDRAM, memory 20 provides a read clock signal for outputting read data and a write clock signal for inputting write data. If the selected DRAM type is a LPDDR-SDRAM, memory 20 provides a differential read clock signal for outputting read data. In one embodiment, the non-selected receiver is not powered.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory device, comprising:
a first receiver configured to receive a single ended clock signal and provide a first clock signal based on the single ended clock signal to provide a memory function; and
a second receiver configured to receive a differential clock signal and provide a second clock signal based on the differential clock signal to provide the memory function, wherein only one of the first receiver and the second receiver is selected to provide the memory function.

2. The memory device of claim 1, comprising:
a memory bank including memory cells, wherein only one of the first receiver and the second receiver is selected to provide the memory function of outputting read data from the memory cells.

3. The memory device of claim 1, comprising:
a command/address block, wherein only one of the first receiver and the second receiver is selected to provide the memory function of executing commands in the command/address block.

4. The memory device of claim 1, wherein the first receiver is configured to provide a read clock signal and a write clock signal and the first clock signal includes one of the read clock signal and the write clock signal.

5. The memory device of claim 4, wherein the first receiver is selected to provide the memory function of outputting read data from the memory cells via the read clock signal and to provide the memory function of inputting write data via the write clock signal.

6. The memory device of claim 1, wherein the second receiver is configured to provide a differential output clock signal and the second clock signal includes the differential output clock signal.

7. The memory device of claim 6, wherein the second receiver is selected to provide the memory function of outputting read data from the memory cells via the differential output clock signal.

8. The memory device of claim 1, comprising:
two input pads, wherein the two input pads receive the differential clock signal and one of the two input pads receives the single ended clock signal.

9. The memory device of claim 1, wherein the selected one of the first receiver and the second receiver consumes power and the other one of the first receiver and the second receiver does not consume power.

10. A random access memory, comprising:
a memory bank including random access memory cells;
a first receiver configured to receive a single ended clock signal and provide a first clock signal based on the single ended clock signal to output read data from the random access memory cells; and
a second receiver configured to receive a differential clock signal and provide a second clock signal based on the differential clock signal to output read data from the random access memory cells, wherein only one of the first receiver and the second receiver is selected to output read data from the random access memory cells.

11. The random access memory of claim 10, wherein the first receiver is configured to receive the single ended clock signal and provide a third clock signal based on the single ended clock signal to input write data.

12. The random access memory of claim 10, comprising:
two input pads, wherein the two input pads receive the differential clock signal and one of the two input pads receives the single ended clock signal.

13. The random access memory of claim 10, wherein the first receiver is selected to provide an SDR-SDRAM.

14. The random access memory of claim 10, wherein the second receiver is selected to provide a DDR-SDRAM.

15. The random access memory of claim 10, wherein one of the first receiver and the second receiver is selected via a metal mask process step.

16. A random access memory, comprising:
means for receiving a single ended clock signal;
means for providing a first clock signal based on the single ended clock signal to provide a random access memory function;
means for receiving a differential clock signal;
means for providing a second clock signal based on the differential clock signal to provide the random access memory function; and
means for selecting only one of the first receiver and the second receiver to provide the random access memory function.

17. The random access memory of claim 16, comprising:
means for outputting read data from random access memory cells via the first clock signal and the second clock signal.

18. The random access memory of claim 16, wherein the means for providing a first clock signal, comprises:
means for providing a read clock signal; and
means for providing a write clock signal.

19. The random access memory of claim 16, wherein the means for providing a second clock signal, comprises:
means for providing a differential output clock signal.

20. The random access memory of claim 16, wherein the means for receiving a single ended clock signal includes one input pad and the means for receiving a differential clock signal includes the one input pad.

21. A method of clocking in a memory, comprising:
providing a first receiver and a second receiver in the memory;
selecting one of the first receiver and the second receiver;
receiving a single ended clock signal at the first receiver;
receiving a differential clock signal at the second receiver;
providing first clock signals based on the single ended clock signal to provide a memory function if the first receiver is selected; and
providing a second clock signal based on the differential clock signal to provide the memory function if the second receiver is selected.

22. The method of claim 21, comprising:
outputting read data from memory cells via the first clock signals if the first receiver is selected and via the second clock signal if the second receiver is selected.

23. The method of claim 21, wherein providing first clock signals comprises:
providing a read clock signal; and
providing a write clock signal.

24. The method of claim 21, wherein providing a second clock signal comprises:
providing a differential output clock signal.

25. The method of claim 21, wherein receiving a single ended clock signal includes receiving the single ended clock signal at one input pad and receiving a differential clock signal includes receiving the differential clock signal at the one input pad and at another input pad.

26. The method of claim 21, wherein selecting one of the first receiver and the second receiver comprises processing a metal mask step that activates the one of the first receiver and the second receiver.

27. A method of clocking in a random access memory, comprising:
storing data in random access memory cells;
receiving a single ended clock signal at a first receiver;
providing a first clock signal based on the single ended clock signal to output read data from the random access memory cells;
receiving a differential clock signal at a second receiver;
providing a second clock signal based on the differential clock signal to output read data from the random access memory cells; and
selecting one of the first receiver and the second receiver to output read data from the random access memory cells.

28. The method of claim 27, comprising:
providing a third clock signal based on the single ended clock signal to input write data.

29. The method of claim 27, comprising:
receiving the differential clock signal at two input pads; and
receiving the single ended clock signal at one of the two input pads.

30. A system, comprising:
an external circuit; and
a memory device configured to transfer data to and receive data from the external circuit, the memory device including:
a first receiver configured to receive a single ended clock signal and provide a first clock signal based on the single ended clock signal to provide a memory function; and
a second receiver configured to receive a differential clock signal and provide a second clock signal based on the differential clock signal to provide the memory function, wherein only one of the first receiver and the second receiver is selected to provide the memory function.

31. The system of claim 30, comprising:
a memory bank including memory cells, wherein only one of the first receiver and the second receiver is selected to provide the memory function of outputting read data from the memory cells.

32. The system of claim 30, comprising:
a command/address block, wherein only one of the first receiver and the second receiver is selected to provide the memory function of executing commands in the command/address block.

33. The system of claim 30, wherein the first receiver is configured to provide a read clock signal and a write clock signal and the first clock signal includes one of the read clock signal and the write clock signal.

34. The system of claim 30, wherein the second receiver is configured to provide a differential output clock signal and the second clock signal includes the differential output clock signal.
